(19) United States
(12) Patent Application Publication
(10) Pub. No.: US 2026/0249632 A1
(43) Pub. Date: Aug. 27, 2026

(54) COATING APPARATUS AND ARTICLE MANUFACTURING METHOD

(71) Applicant: CANON KABUSHIKI KAISHA, Tokyo (JP)

(72) Inventors: YUJI YOSHIBA, Tochigi (JP); KOUHEI NAGANO, Saitama (JP); HIROKI NAKANO, Tochigi (JP); JUMPEI HAYASHI, Kanagawa (JP)

(21) Appl. No.: 19/546,570

(22) Filed: Feb. 23, 2026

(30) Foreign Application Priority Data
Feb. 25, 2025 (JP) 2025-028239

(51) Int. Cl. B41J 29/393; B41J 2/165; B41J 11/06; B41J 11/14; B41J 25/304; H10K 71/13

(52) U.S. Cl. CPC B41J 29/393; B41J 2/16579; B41J 11/06; B41J 11/14; B41J 25/304; H10K 71/13

(57) ABSTRACT

A coating apparatus for applying droplets to a substrate, includes a plurality of heads configured to discharge the droplets, a conveying mechanism configured to convey the plurality of heads in a first direction such that one head in the plurality of heads is arranged in a first region and another head in the plurality of heads is arranged in a second region, a moving mechanism configured to move one head in the plurality of heads between the first region and a coating region, and a scanning mechanism configured to scan the substrate in the first direction such that the droplets are applied to the substrate by the head arranged in the coating region in the plurality of heads, wherein at least a part of the second region is arranged above the scanning mechanism.

### BACKGROUND

### Field of the Technology

The present disclosure relates to a coating apparatus and an article manufacturing method.

### Description of the Related Art

Japanese Patent Laid-Open No. 2006-187758 describes a droplet discharge apparatus for drawing droplets on a workpiece such as a glass substrate. The droplet discharge apparatus includes a droplet discharge portion, two maintenance portions, a table, a first moving portion, a second moving portion, and a plurality of carriages. The first moving portion includes a base extending in the X direction, a slide member that is driven in the X direction on the base by a linear motor, and a table that is driven in the X direction on the slide member by the linear motor, and a workpiece is held by the table. The first moving portion has a shape long in the X direction as a whole. The second moving portion extends in the Y direction to be orthogonal to the first moving portion and moves each carriage along the Y direction.

As described in Japanese Patent Laid-Open No. 2006-187758, in the configuration in which the second moving portion extending in the Y direction is arranged on the first moving portion extending in the X direction, the space above the first moving portion cannot effectively be used.

### SUMMARY

The present disclosure provides a coating apparatus having a configuration advantageous for effectively using a space.

The present disclosure provides a coating apparatus for applying droplets to a substrate, comprising: a plurality of heads configured to discharge the droplets; a conveying mechanism configured to convey the plurality of heads in a first direction such that one head in the plurality of heads is arranged in a first region and another head in the plurality of heads is arranged in a second region; a moving mechanism configured to move one head in the plurality of heads between the first region and a coating region; and a scanning mechanism configured to scan the substrate in the first direction such that the droplets are applied to the substrate by the head arranged in the coating region in the plurality of heads, wherein at least a part of the second region is arranged above the scanning mechanism.

Features of the present disclosure will become apparent from the following description of embodiments with reference to the attached drawings. The following description of embodiments is described by way of example.

### BRIEF DESCRIPTION OF THE DRAWINGS

FIG. 1 is a perspective view schematically showing the configuration of coating apparatuses according to the first to fourth embodiments;

FIG. 2 is a sectional view schematically showing the configuration of a coating apparatus according to the first embodiment;

FIG. 3 is a sectional view schematically showing the configuration of the coating apparatus according to the first embodiment;

FIG. 4 is a sectional view schematically showing the configuration of the coating apparatus according to the first embodiment;

FIG. 5 is a sectional view schematically showing the configuration of the coating apparatus according to the first embodiment;

FIG. 6 is a sectional view schematically showing the configuration of the coating apparatus according to the first embodiment;

FIG. 7 is a sectional view schematically showing the configuration of the coating apparatus according to the first embodiment;

FIG. 8 is a sectional view schematically showing the configuration of the coating apparatus according to the first embodiment;

FIG. 9 is a sectional view schematically showing the configuration of the coating apparatus according to the first embodiment;

FIG. 10 is a sectional view schematically showing the configuration of a coating apparatus according to the second embodiment;

FIG. 11 is a sectional view schematically showing the configuration of the coating apparatus according to the second embodiment;

FIG. 12 is a sectional view schematically showing the configuration of the coating apparatus according to the second embodiment;

FIG. 13 is a sectional view schematically showing the configuration of the coating apparatus according to the second embodiment;

FIG. 14 is a sectional view schematically showing the configuration of the coating apparatus according to the second embodiment;

FIG. 15 is a sectional view schematically showing the configuration of the coating apparatus according to the second embodiment;

FIG. 16 is a sectional view schematically showing the configuration of the coating apparatus according to the second embodiment;

FIG. 17 is a sectional view schematically showing the configuration of the coating apparatus according to the second embodiment;

FIG. 18 is a sectional view schematically showing the configuration of a coating apparatus according to the third embodiment;

FIG. 19 is a sectional view schematically showing the configuration of the coating apparatus according to the third embodiment;

FIG. 20 is a sectional view schematically showing the configuration of a coating apparatus according to the fourth embodiment;

FIG. 21 is a sectional view schematically showing the configuration of the coating apparatus according to the fourth embodiment; and

FIG. 22 is a sectional view schematically showing the configuration of the coating apparatus according to the fourth embodiment.

The accompanying drawings, which are incorporated in and constitute a part of the specification, illustrate embodiments of the present disclosure, and together with the description, serve to explain the principles of the embodiments.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

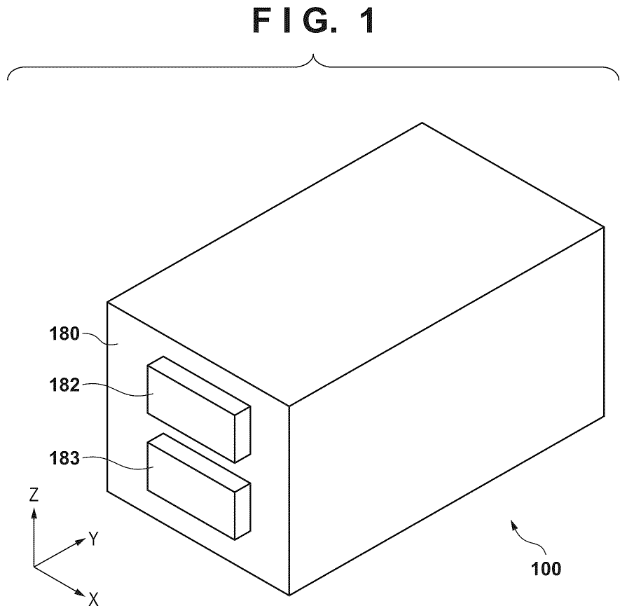

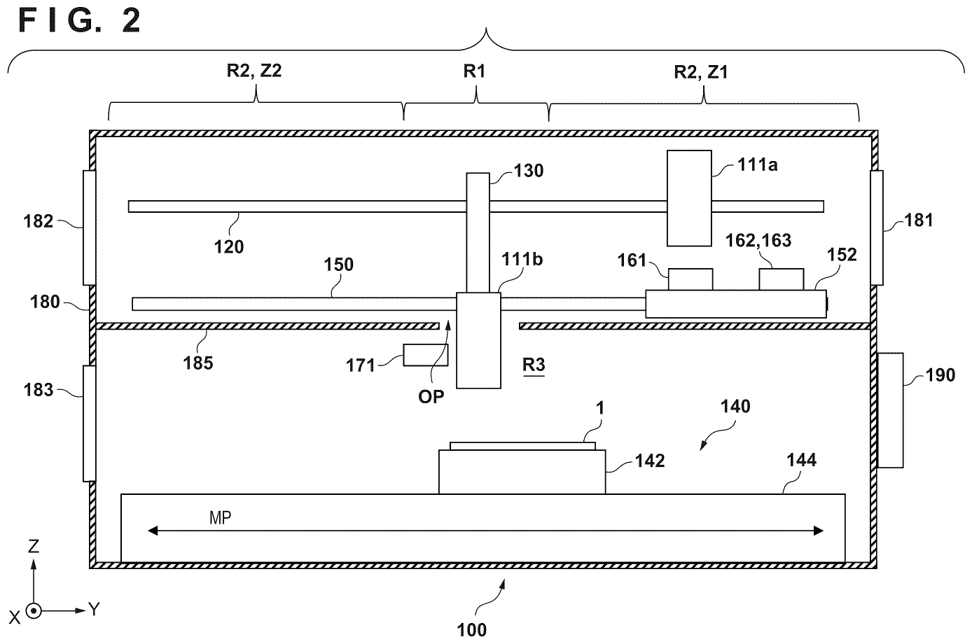

FIG. 1 is a perspective view schematically showing the configuration of a coating apparatus 100 according to the first embodiment. FIGS. 2 to 9 are sectional views schematically showing the configuration and operation of the coating apparatus 100 according to the first embodiment. In this specification and drawings, the configuration of each constituent element, the mutual positional relationship between the constituent elements, the moving direction of each constituent element, and the like will be described under an XYZ coordinate system. The XY plane in the XYZ coordinate system is parallel to a horizontal surface. Directions parallel to the X-, Y-, and Z-axes of the XYZ coordinate system are the X-axis direction, the Y-axis direction, and the Z-axis direction. The X-axis direction includes the positive and negative directions of the X-axis, the Y-axis direction includes the positive and negative directions of the Y-axis, and the Z-axis direction includes the positive and negative directions of the Z-axis. In the following explanation, the first direction is the Y-axis direction, and the second direction is the X-axis direction.

The coating apparatus 100 applies droplets to a substrate 1. Applying droplets to the substrate 1 means arranging droplets at a target position or in a target region of the substrate 1. The droplets can be made of a liquid containing an organic substance. The droplet is sometimes called ink. The organic substance is, for example, a material used to form an organic film of an organic EL (OLED) display. The organic film can be, for example, one of a hole injection layer, a hole transport layer, a light emitting layer, an electron transport layer, and an electron injection layer. A process for manufacturing an organic EL display can include a step of forming an organic film such as a hole injection layer, a hole transport layer, a light emitting layer, an electron transport layer, or an electron injection layer on a substrate.

The coating apparatus 100 includes heads 111a and 111b as a plurality of heads configured to apply droplets. Note that in the following explanation, as for matters common to the heads 111a and 111b, these will be described as a head 111. In addition, if the heads 111a and 111b will be described distinctively, these will be described as the head 111a and the head 111b. In the coating apparatus 100 according to the first embodiment, when coating processing of applying droplets to the substrate 1 is being performed using one head 111 in the plurality of heads 111, maintenance for the other head 111 in the plurality of heads 111 can be performed. Hence, according to the coating apparatus 100 of the first embodiment, it is possible to suppress downtime in execution of maintenance and operate the coating apparatus 100 at a high operating efficiency.

The coating apparatus 100 can include a conveying mechanism 120 that conveys the plurality of heads 111 in the first direction (Y-axis direction) such that one head 111 in the plurality of heads 111 is arranged in a first region R1 and the other head 111 in the plurality of heads 111 is arranged in a second region R2. The coating apparatus 100 can also include a moving mechanism 130 that moves one head 111 in the plurality of heads 111 between the first region R1 and a coating region R3. The coating apparatus 100 can also include a scanning mechanism 140 that scans the substrate 1 in the first direction (Y-axis direction) such that droplets are applied to (each target position of) the substrate 1 by the head 111 arranged in the coating region R3 among the plurality of heads 111. At least a part of the second region R2 can be arranged above the scanning mechanism 140. This configuration is advantageous for effectively using a space. The moving mechanism 130 is, for example, an elevating mechanism. The first region R1 is located, for example, at a position above the coating region R3 (the positive direction of the Z-axis).

The scanning mechanism 140 can include a stage 142 that holds the substrate 1, and a driving mechanism 144 that moves the stage 142 along a moving path MP parallel to the first direction (Y-axis direction). In orthogonal projection (planar view) onto the XY plane, the first region R1 and the second region R2 are apart in the first direction (Y-axis direction). The size of the plurality of heads 111 in the second direction (X-axis direction) orthogonal to the first direction (Y-axis direction) is preferably larger than the size of the substrate 1 held by the scanning mechanism 140 in the second direction. This configuration is advantageous for shortening time necessary for applying droplets to a plurality of target positions of the substrate 1.

In the second region R2, maintenance can be performed for the head 111 arranged in the second region R2 in the plurality of heads 111. Maintenance can include, for example, at least one of cleaning, inspection, and exchange. The coating apparatus 100 can include a cleaning portion 161 that cleans the head 111 arranged in the second region R2 in the plurality of heads 111. The coating apparatus 100 can include an inspection portion 162 that inspects the head 111 arranged in the second region R2 in the plurality of heads 111.

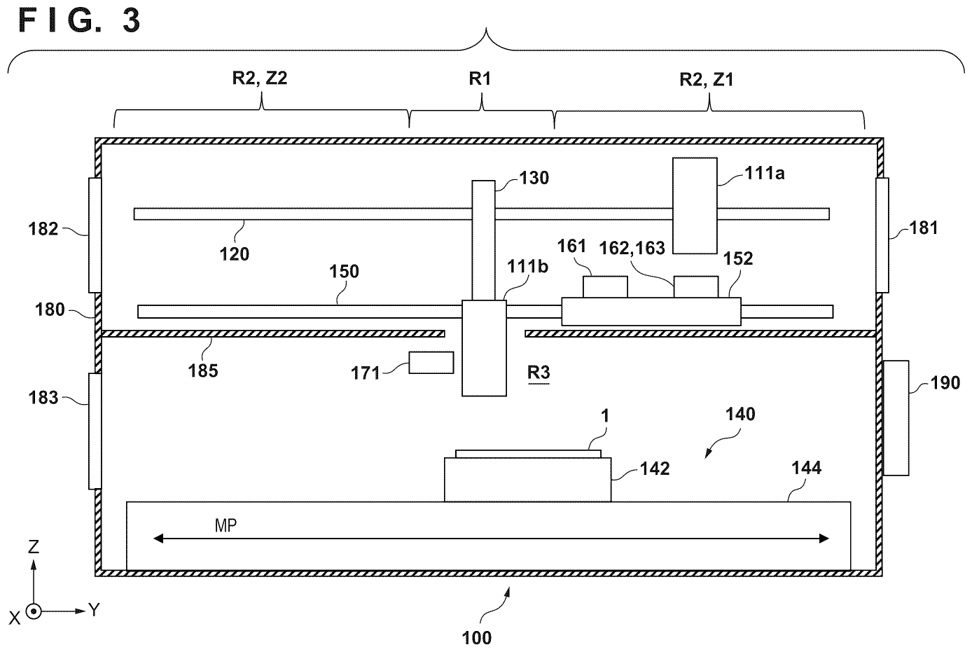

FIG. 2 schematically shows a state in which for the head 111a arranged in the second region R2 in the plurality of heads 111, cleaning is performed by the cleaning portion 161. The cleaning by the cleaning portion 161 can include sucking a liquid in a plurality of nozzles of the head 111. Alternatively, the cleaning by the cleaning portion 161 can include supplying a cleaning liquid to the head end face with the plurality of nozzles, thereby removing a foreign substance adhered to the head end face and/or wiping the head end face. In the coating apparatus 100, when the cleaning portion 161 is cleaning the head 111a, droplets can be applied to the substrate 1 using the head 111b. FIG. 3 schematically shows a state in which for the head 111a arranged in the second region R2 in the plurality of heads 111, inspection is performed by the inspection portion 162. In the coating apparatus 100, when the inspection portion 162 is inspecting the head 111a, droplets can be applied to the substrate 1 using the head 111b.

The cleaning portion 161 and the inspection portion 162 can form a maintenance portion 152 that performs maintenance for the head 111 arranged in the second region R2 in the plurality of heads 111. The maintenance portion 152 may be formed by at least one maintenance element of the cleaning portion 161 and the inspection portion 162 or may be replaced with another maintenance element, or another maintenance element may be added.

The coating apparatus 100 may include a second conveying mechanism 150 that moves the maintenance portion 152 in the first direction (Y-axis direction). The second region R2 may include a first section Z1 and a second section Z2. In this case, the first region R1 can be arranged between the first section Z1 and the second section Z2. The first section Z1 and the second section Z2 are apart in the first direction (Y-axis direction). The second conveying mechanism 150 can be configured to be able to arrange the maintenance portion 152 in any of the first section Z1 and the second section Z2.

The inspection portion 162 can inspect, for example, whether droplets are discharged from the nozzles of the head 111. The inspection portion 162 may include a measurement portion 163 that measures the characteristic of the head 111 arranged in the second region R2 in the plurality of heads 111. The measurement portion 163 can measure, for example, at least one of the discharge speed of a droplet from a nozzle of the head 111, the volume of a droplet from a nozzle of the head 111, the discharge angle of a droplet from a nozzle of the head 111, and the landing position of a droplet from a nozzle of the head 111. The measurement portion 163 is useful for reducing variations of the coating characteristic caused by the individual difference of the head 111 and the temporal change of the characteristic of the head 111. The measurement portion 163 can include, for example, at least one of a camera, an interferometer, and a phase doppler measurement device. The coating apparatus 100 can further include a processor 190 that generates, based on a result of measurement by the measurement portion 163, correction data for controlling the operation of the head 111 applying droplets to the substrate 1 in the coating region R3, which is measured by the measurement portion 163.

The processor 190 can be formed by, for example, a PLD (short for Programmable Logic Device) such as an FPGA (short for Field Programmable Gate Array), an ASIC (short for Application Specific Integrated Circuit), a general-purpose or dedicated computer with a program installed, or a combination of some or all of these. The processor 190 may be formed as a controller that controls the operation of the coating apparatus 100 by controlling the constituent elements of the coating apparatus 100 or may be provided independently of the controller.

The coating apparatus 100 may further include a second measurement portion 171 that measures the head 111 held by the moving mechanism 130 in the plurality of heads 111. The processor 190 may generate, based on a result of measurement by the measurement portion 163 and the second measurement portion 171, correction data for controlling the operation of the head 111 applying droplets to the substrate 1 in the coating region R3. The second measurement portion 171 can measure, for example, at least one of the position and the posture of the head 111 held by the moving mechanism 130. This is useful for reducing variations of the coating characteristic caused by the positioning error of head 111 existing in a state in which the head 111 arranged in the first region R1 by the conveying mechanism 120 is held by the moving mechanism 130.

The plurality of heads 111, the conveying mechanism 120, the moving mechanism 130, the scanning mechanism 140, the second conveying mechanism 150, and the maintenance portion 152 can be arranged in the internal space of a chamber 180. The internal space of the chamber 180 can be divided into a first layer and a second layer by a separation panel 185 having an opening OP configured to arrange the selected head 111 in the plurality of heads 111 in the first region R1 and the coating region R3. In the first layer, the scanning mechanism 140 can be arranged. In the second layer, the conveying mechanism 120, the moving mechanism 130, the scanning mechanism 140, the second conveying mechanism 150, and the maintenance portion 152 can be arranged. In the chamber 180, a gate 183 configured to convey the substrate 1 from the external space of the chamber 180 into the internal space or convey the substrate 1 from the internal space to the external space is provided. The substrate 1 processed by a preceding process is conveyed from the gate 183 and transfer of the substrate 1 to the scanning mechanism 140 can be done on the side of the gate 183 in the first layer. Also, the position of the substrate 1 can be measured by a measurement device (not shown), and the mutual positional relationship between the substrate 1 and the scanning mechanism 140 can be adjusted. Hence, a space is needed in the Y-axis direction of the first layer, and arranging the conveying mechanism 120 such that it extends in the Y direction is useful for utilizing the space.

The coating apparatus 100 can be configured to be able to exchange the head 111 arranged in the second region R2 in the plurality of heads 111 with another head (for example, a new head or a recycled head). Exchange of the head 111 may be performed by a robot (not shown) or an operator. The chamber 180 is provided with access portions 181 and 182 (for example, doors) used to access from the external space of the chamber 180 to the internal space, and the head 111 can be exchanged with another head through the access portions 181 and 182.

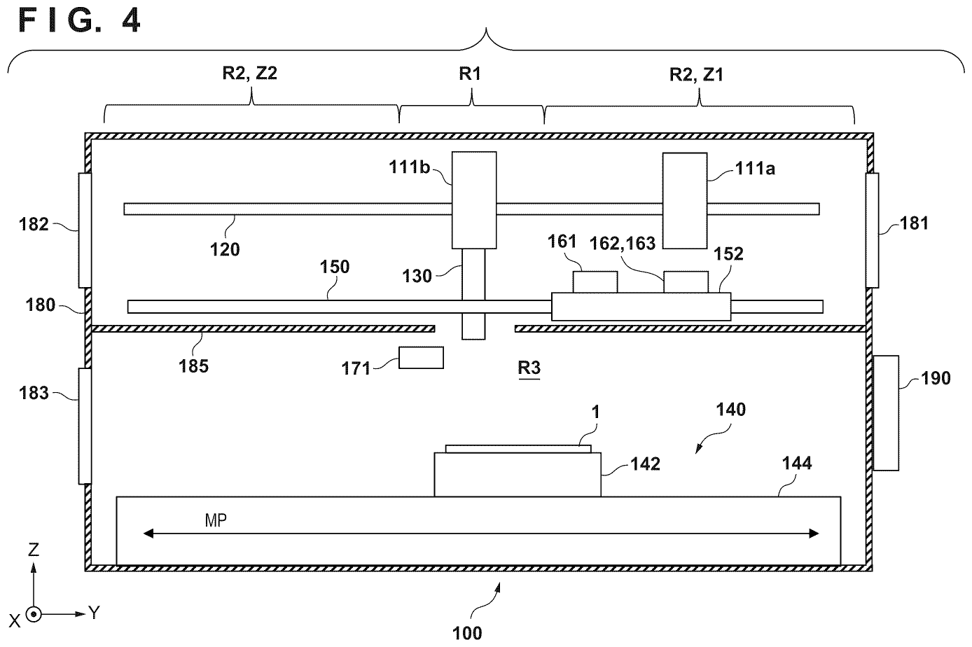

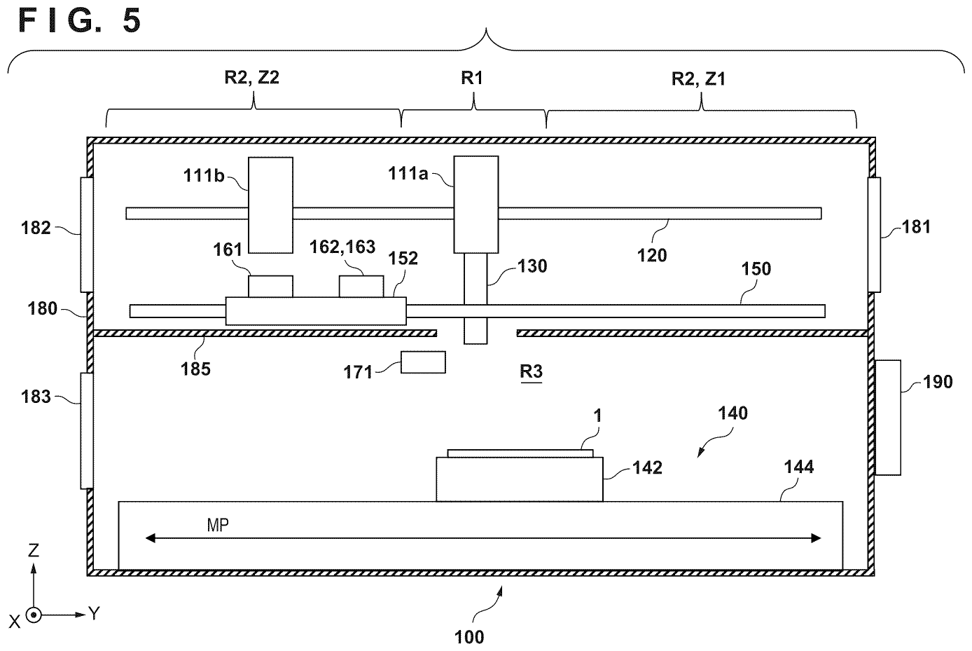

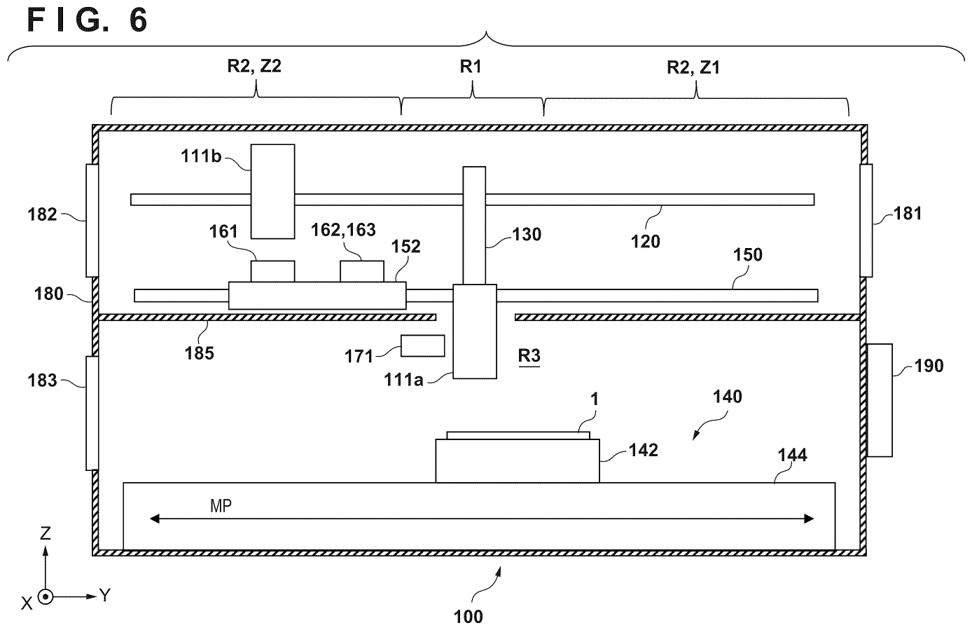

An operation of exchanging the head 111b used to apply droplets to the substrate with the head 111a will exemplarily be described below. First, as schematically shown in FIG. 4, the head 111b arranged in the coating region R3 can be moved to the first region R1 by the moving mechanism 130. Next, as schematically shown in FIG. 5, the head 111b arranged in the first region R1 can be moved to the second section Z2 of the second region R2 by the conveying mechanism 120. Also, the maintenance portion 152 arranged in the first section Z1 of the second region R2 can be moved to the second section Z2 of the second region R2 by the second conveying mechanism 150. In addition, the head 111a arranged in the first section Z1 of the second region R2 can be moved to the first region R1 by the conveying mechanism 120. Next, as schematically shown in FIG. 6, the head 111a arranged in the first region R1 can be moved to the coating region R3 by the moving mechanism 130.

At this time, the second measurement portion 171 can measure the state of the head 111a held by the moving mechanism 130. Also, the processor 190 can generate, based on a result of measurement by the measurement portion 163 and the second measurement portion 171, correction data for controlling the operation of the head 111a applying droplets to the substrate 1 in the coating region R3. The operation of exchanging the head 111b with the head 111a can thus be completed. In this state, application of droplets to the substrate 1 can be performed using the head 111a arranged in the coating region R3.

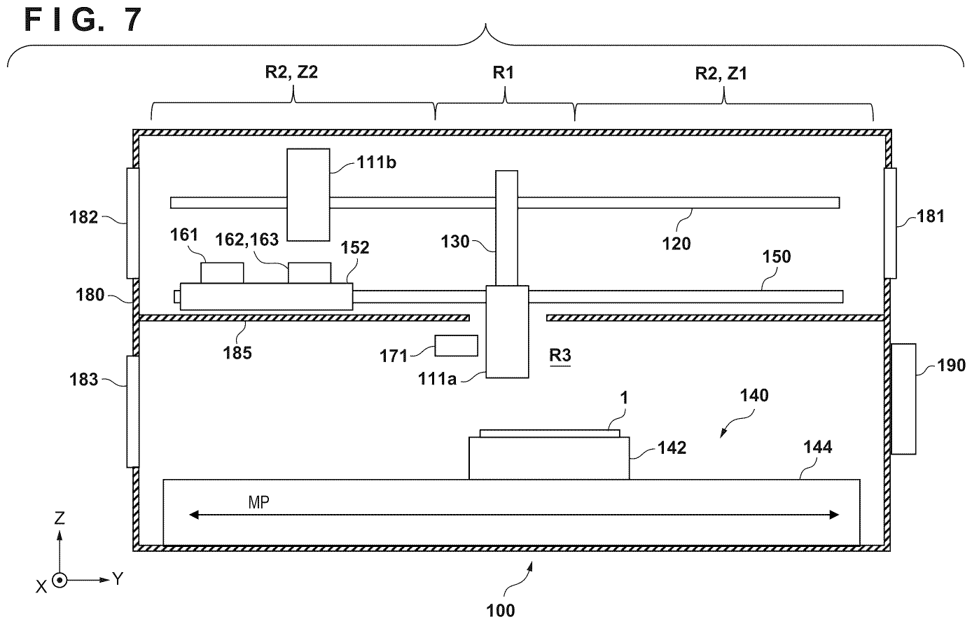

In the state schematically shown in FIG. 6, furthermore, cleaning can be performed by the cleaning portion 161 for the head 111b arranged in the second section Z2 of the second region R2 in the plurality of heads 111. Next, as schematically shown in FIG. 7, inspection can be performed by the inspection portion 162 for the head 111b arranged in the second section Z2 of the second region R2 in the plurality of heads 111. Cleaning of the head 111b by the cleaning portion 161 can be performed in parallel to the coating operation of applying droplets to the substrate 1 using the head 111a arranged in the coating region R3. In addition, inspection of the head 111b by the inspection portion 162 can be performed in parallel to the coating operation of applying droplets to the substrate 1 using the head 111a arranged in the coating region R3. That is, maintenance of the head 111b by the maintenance portion 152 can be performed in parallel to the coating operation of applying droplets to the substrate 1 using the head 111a arranged in the coating region R3.

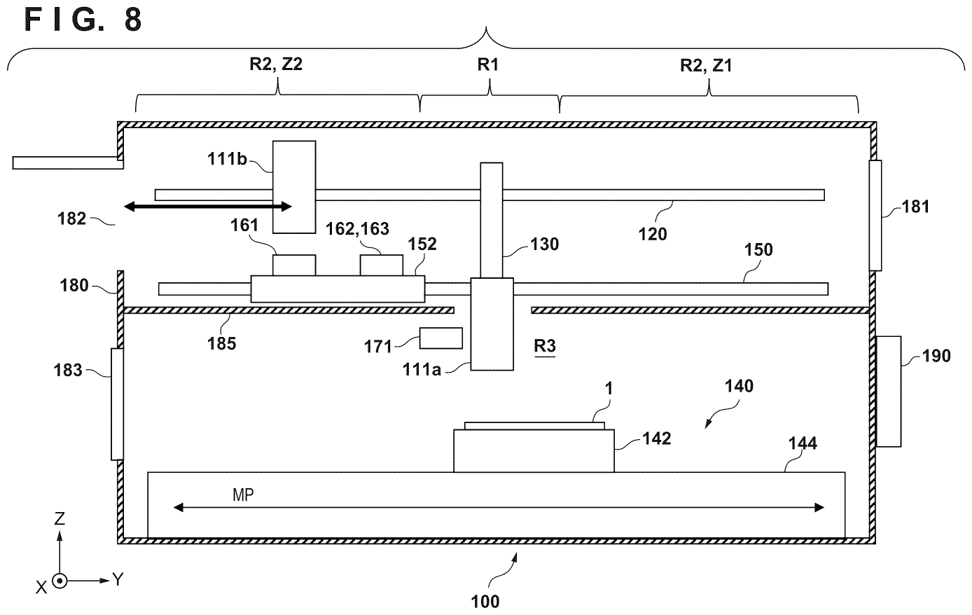

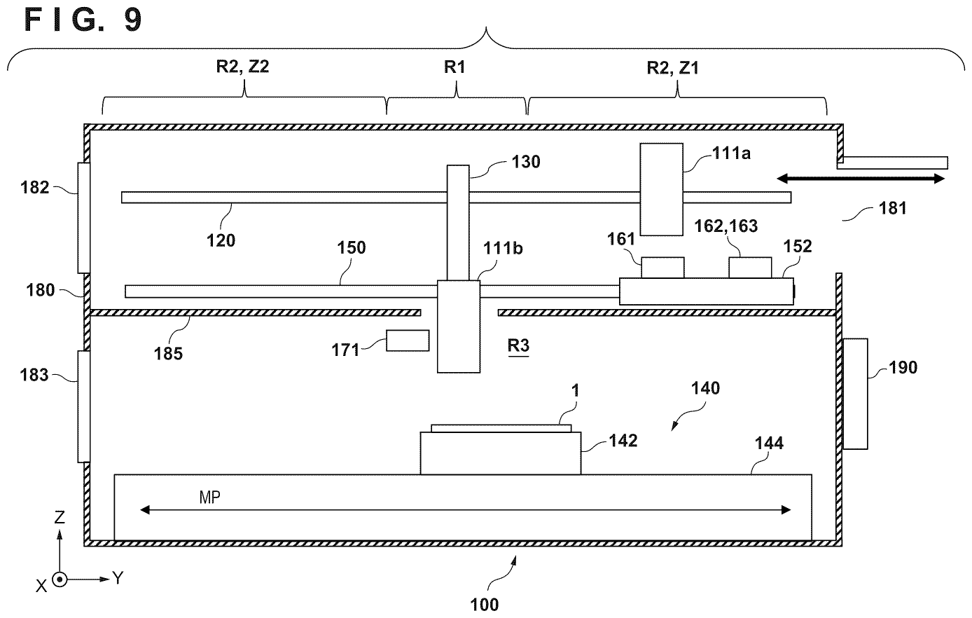

FIG. 8 schematically shows a state in which the head 111b arranged in the second section Z2 of the second region R2 in the plurality of heads 111 is exchanged through the access portion 182. FIG. 9 schematically shows a state in which the head 111a arranged in the first section Z1 of the second region R2 in the plurality of heads 111 is exchanged through the access portion 181.

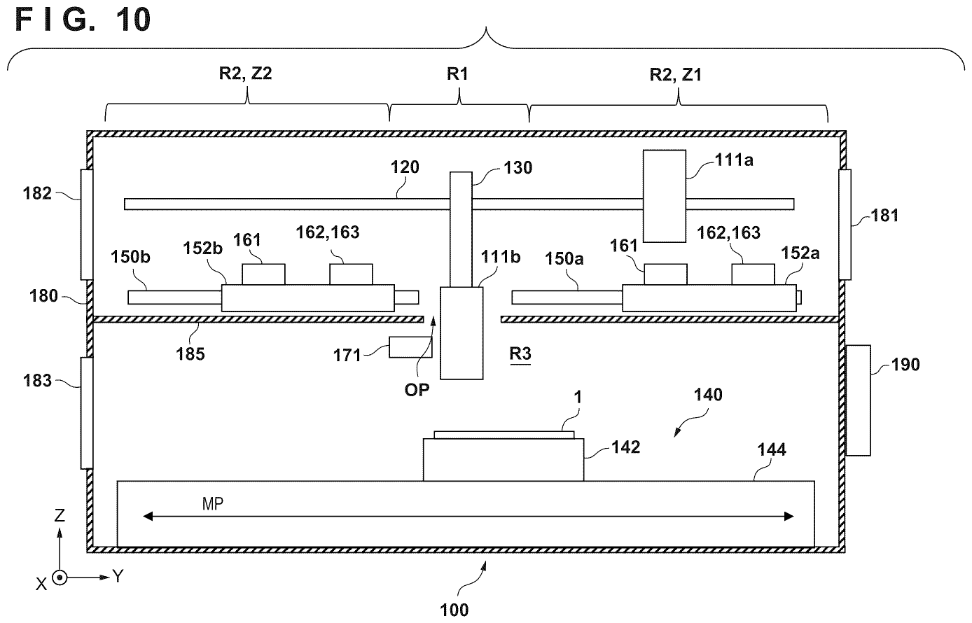

The configuration and operation of a coating apparatus 100 according to the second embodiment will be described below with reference to FIGS. 10 to 17. Matters not described concerning the coating apparatus 100 according to the second embodiment can comply with the explanation in the first embodiment. In the second embodiment, a plurality of heads 111 include a head 111a and a head 111b. In a second region R2, a first maintenance portion 152a configured to perform maintenance of the head 111a and a second maintenance portion 152b configured to perform maintenance of the head 111b can be arranged. More specifically, the first maintenance portion 152a can be arranged in a first section Z1 of the second region R2, and the second maintenance portion 152b can be arranged in a second section Z2 of the second region R2. The first maintenance portion 152a and the second maintenance portion 152b can have the same configuration as the maintenance portion 152 in the first embodiment. The first maintenance portion 152a can be conveyed by a first conveying mechanism 150a, and the second maintenance portion 152b can be conveyed by a second conveying mechanism 150b. Note that the coating apparatus 100 may be configured not to include the first conveying mechanism 150a and the second conveying mechanism 150b.

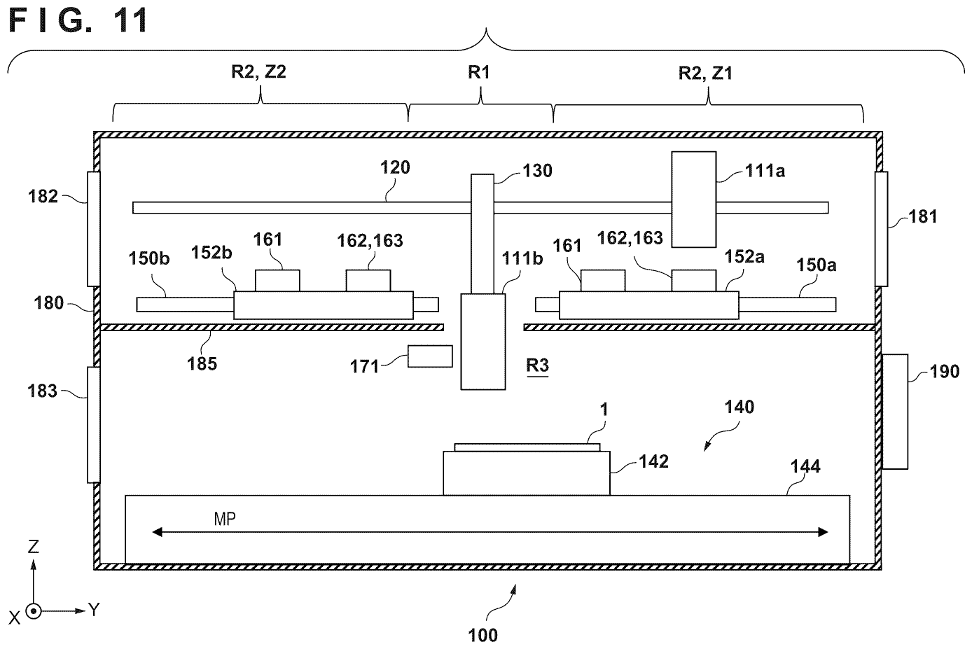

In the state shown in FIG. 10, processing of cleaning the head 111a by a cleaning portion 161 of the first maintenance portion 152a can be performed in parallel to the processing of applying droplets to a substrate 1 using the head 111b. In the state shown in FIG. 11, processing of inspecting the head 111a by an inspection portion 162 of the first maintenance portion 152a can be performed in parallel to the processing of applying droplets to the substrate 1 using the head 111b. This inspection can include measurement by a measurement portion 163 provided in the inspection portion 162 of the first maintenance portion 152a.

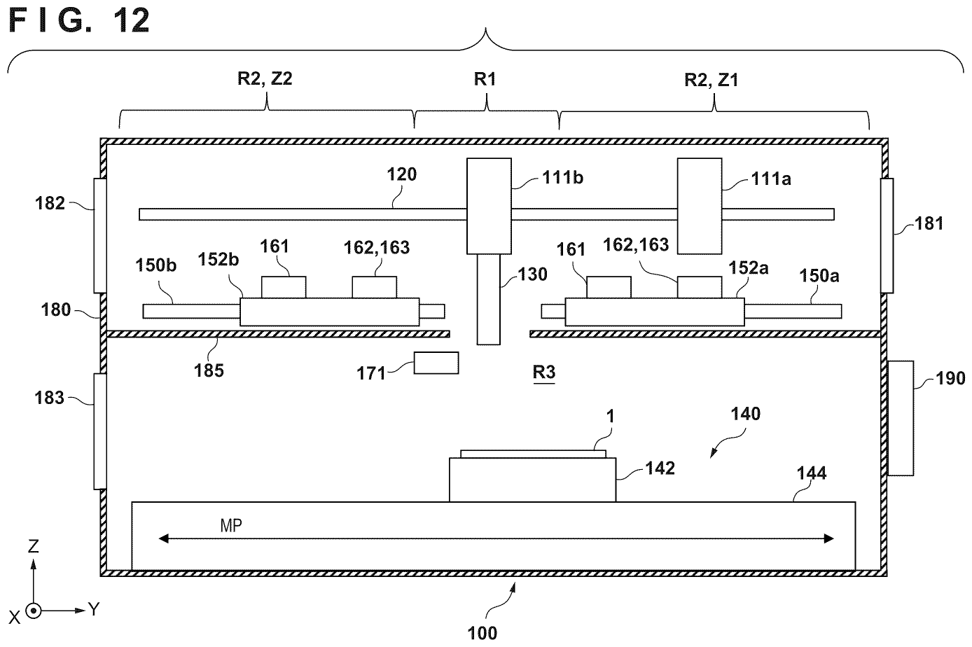

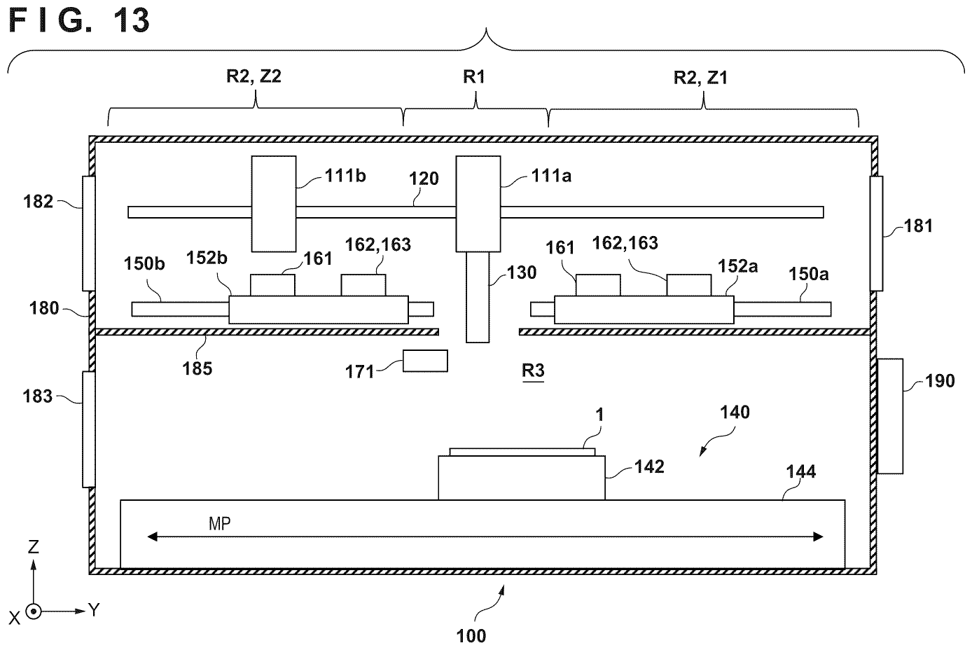

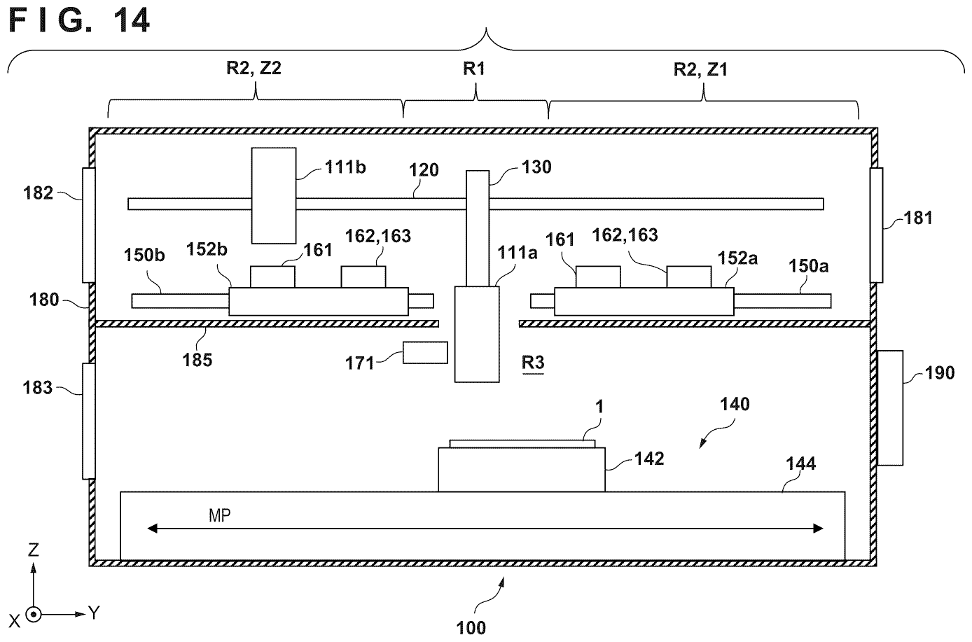

An operation of exchanging the head 111b used to apply droplets to the substrate with the head 111a will exemplarily be described below. First, as schematically shown in FIG. 12, the head 111b arranged in a coating region R3 can be moved to a first region R1 by a moving mechanism 130. Next, as schematically shown in FIG. 13, the head 111b arranged in the first region R1 can be moved to the second section Z2 of the second region R2 by a conveying mechanism 120. Also, the head 111a arranged in the first section Z1 of the second region R2 can be moved to the first region R1 by the conveying mechanism 120. Next, as schematically shown in FIG. 14, the head 111a arranged in the first region R1 can be moved to the coating region R3 by the moving mechanism 130.

At this time, a second measurement portion 171 can measure the state of the head 111a held by the moving mechanism 130. Also, a processor 190 can generate, based on a result of measurement by the measurement portion 163 and the second measurement portion 171, correction data for controlling the operation of the head 111a applying droplets to the substrate 1 in the coating region R3. The operation of exchanging the head 111b with the head 111a can thus be completed. In this state, application of droplets to the substrate 1 can be performed using the head 111a arranged in the coating region R3.

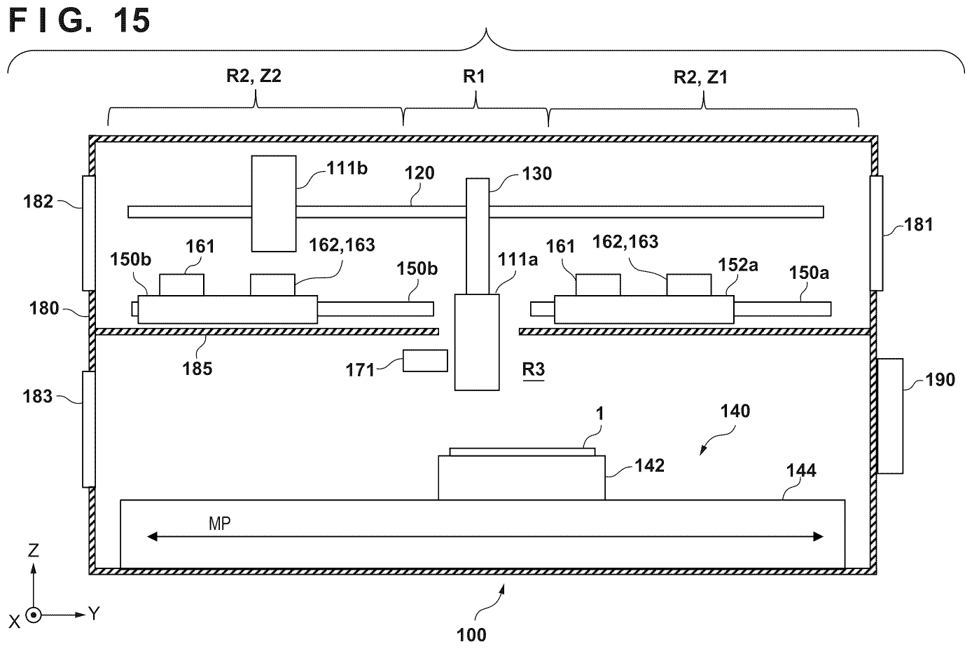

In the state schematically shown in FIG. 14, furthermore, cleaning can be performed by the cleaning portion 161 of the second maintenance portion 152b for the head 111b arranged in the second section Z2 of the second region R2. Next, as schematically shown in FIG. 15, inspection can be performed by the inspection portion 162 of the second maintenance portion 152b for the head 111b arranged in the second section Z2 of the second region R2 in the plurality of heads 111.

Cleaning of the head 111b by the cleaning portion 161 of the second maintenance portion 152b can be performed in parallel to the coating operation of applying droplets to the substrate 1 using the head 111a arranged in the coating region R3. In addition, inspection of the head 111b by the inspection portion 162 of the second maintenance portion 152b can be performed in parallel to the coating operation of applying droplets to the substrate 1 using the head 111a arranged in the coating region R3. That is, maintenance of the head 111b by the maintenance portion 152 can be performed in parallel to the coating operation of applying droplets to the substrate 1 using the head 111a arranged in the coating region R3.

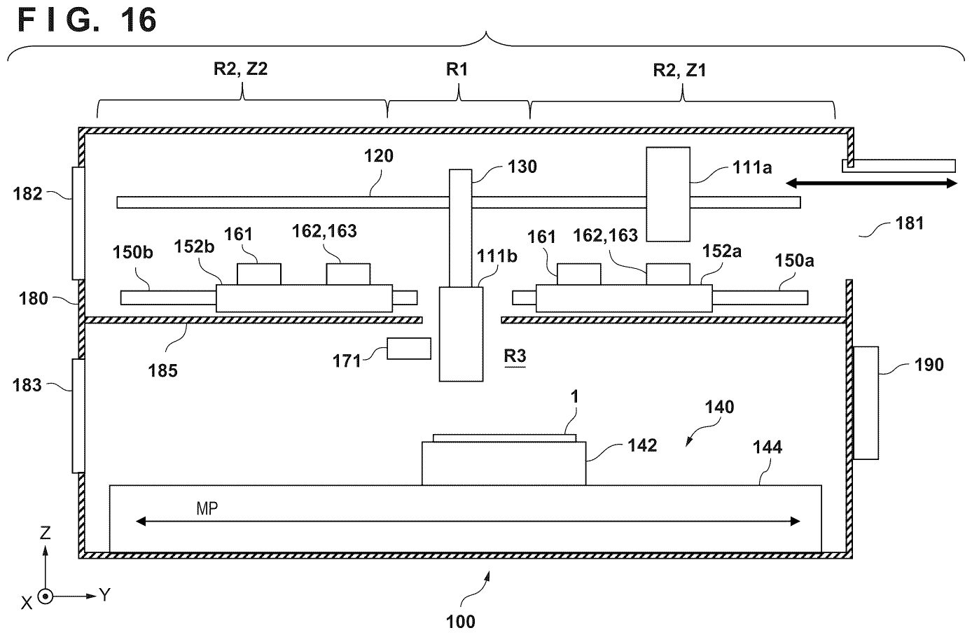

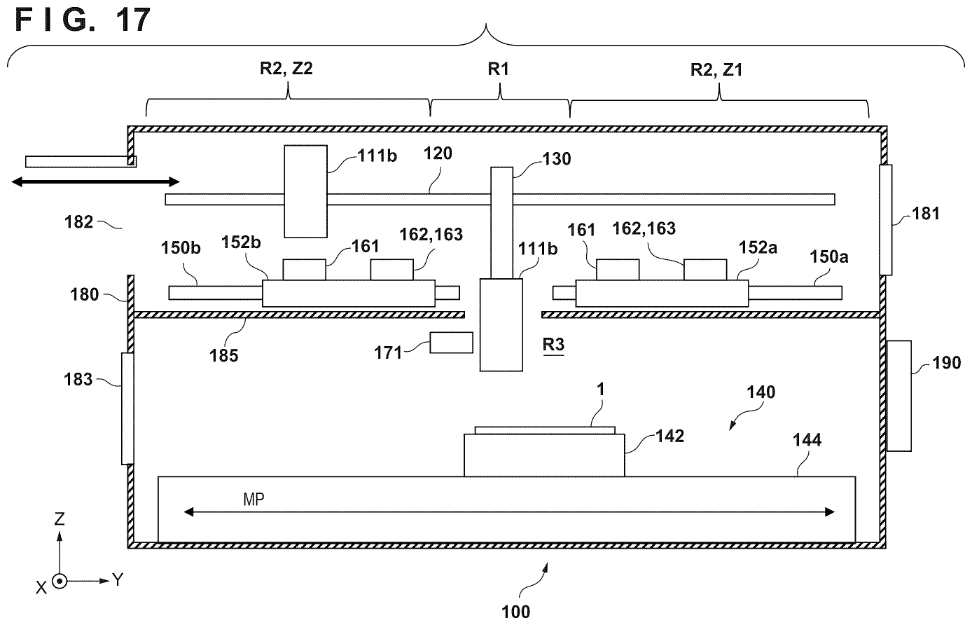

FIG. 16 schematically shows a state in which the head 111a arranged in the first section Z1 of the second region R2 is exchanged through an access portion 181. FIG. 17 schematically shows a state in which the head 111b arranged in the second section Z2 of the second region R2 is exchanged through an access portion 182.

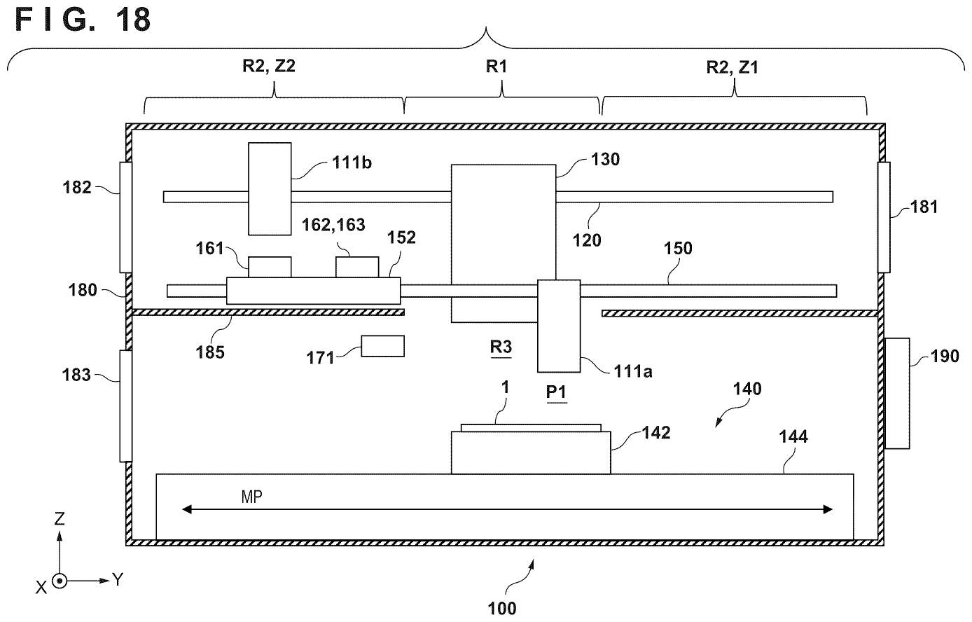

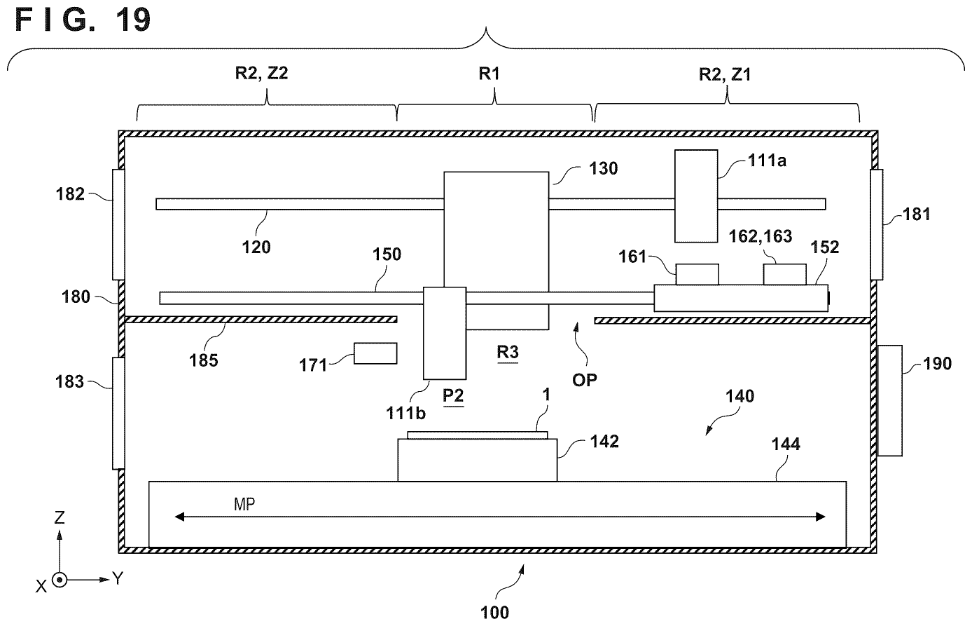

The configuration and operation of a coating apparatus 100 according to the third embodiment will be described below with reference to FIGS. 18 and 19. Matters not described concerning the coating apparatus 100 according to the third embodiment can comply with the explanation in the first or second embodiment. In the third embodiment, a coating region R3 includes a first position P1 at which a head 111a is arranged such that droplets are applied to a substrate 1 by the head 111a, and a second position P2 at which a head 111b is arranged such that droplets are applied to the substrate 1 by the head 111b. The first position P1 and the second position P2 are different positions, and are different positions particularly concerning a first direction (Y-axis direction). The third embodiment is advantageous for making the stroke of a conveying mechanism 120 small.

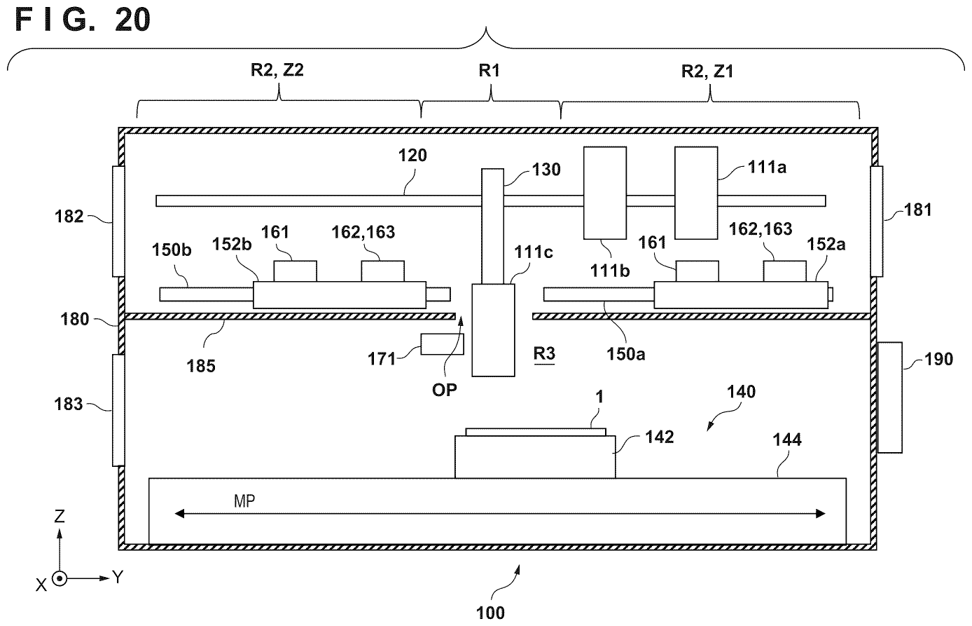

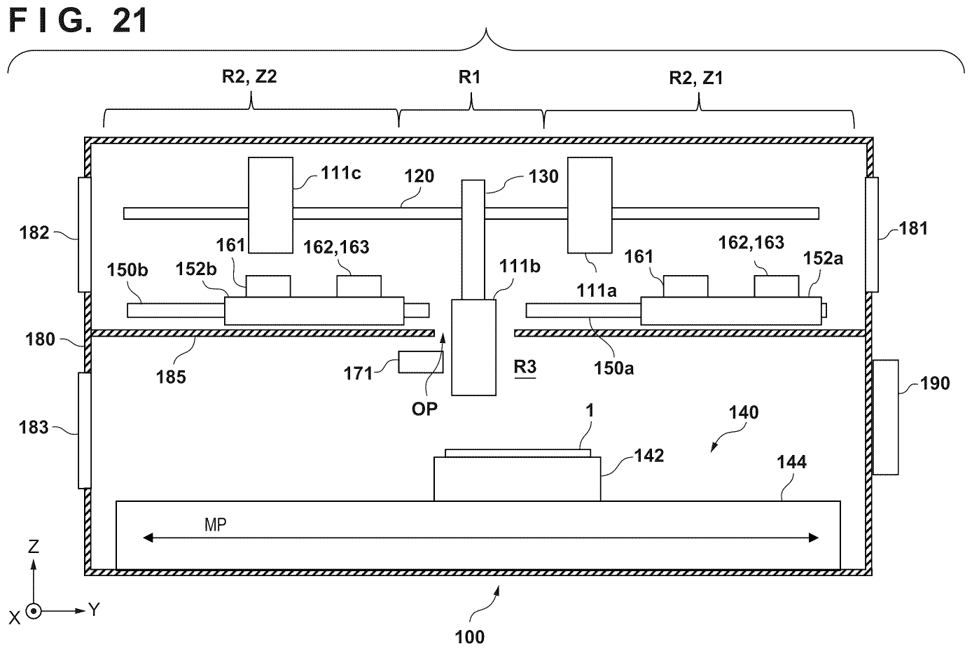

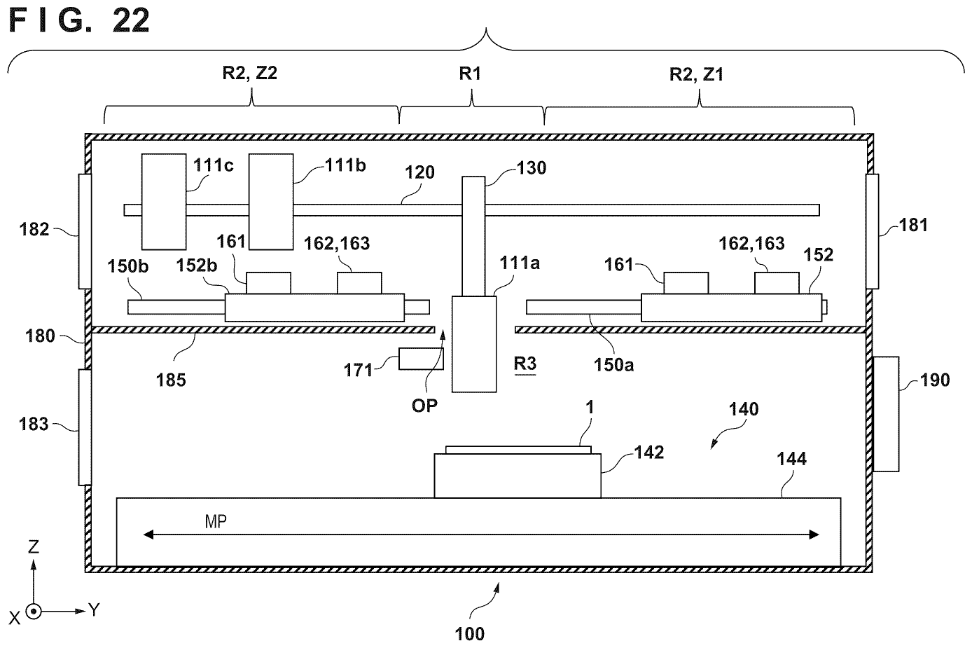

The configuration and operation of a coating apparatus 100 according to the fourth embodiment will be described below with reference to FIGS. 20 to 22. Matters not described concerning the coating apparatus 100 according to the fourth embodiment can comply with the explanation in the first to third embodiments. In the fourth embodiment, the coating apparatus 100 includes three heads 111a, 111b, and 111c. Note that the coating apparatus 100 may include four or more heads 111. In the state shown in FIG. 20, the heads 111a and 111b are arranged in a first section Z1 of a second region R2, and the head 111c is arranged in a coating region R3. In the state shown in FIG. 21, the head 111a is arranged in the first section Z1 of the second region R2, the head 111b is arranged in the coating region R3, and the head 111c is arranged in a second section Z2 of the second region R2. In the state shown in FIG. 22, the head 111a is arranged in the coating region R3, and the heads 111b and 111c are arranged in the second section Z2 of the second region R2.

An article manufacturing method of manufacturing an article such as an organic EL (OLED) display using the coating apparatus 100 will exemplarily be described below. The article manufacturing method can include, for example, a coating step of applying droplets to the substrate 1 such as a glass substrate or a resin substrate by the coating apparatus 100, and a processing step of processing the substrate 1 that has undergone the coating step, thereby obtaining an article. The processing step can include, for example, a step of forming a dry film by drying the droplets applied to the substrate 1 in the coating step, and a step of forming an organic film by baking the dry film. The processing step can also include a step of forming an upper electrode on the organic film, and a step of forming a sealing film covering the upper electrode. The article manufacturing method can also include, before the coating step, a step of forming a driving circuit on the substrate 1, and a step of forming a lower electrode on the driving circuit.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-028239, filed Feb. 25, 2025, which is hereby incorporated by reference herein in its entirety.

What is claimed is:

1. A coating apparatus for applying droplets to a substrate, comprising:
a plurality of heads configured to discharge the droplets;
a conveying mechanism configured to convey the plurality of heads in a first direction such that one head in the plurality of heads is arranged in a first region and another head in the plurality of heads is arranged in a second region;
a moving mechanism configured to move one head in the plurality of heads between the first region and a coating region; and
a scanning mechanism configured to scan the substrate in the first direction such that the droplets are applied to the substrate by the head arranged in the coating region in the plurality of heads,
wherein at least a part of the second region is arranged above the scanning mechanism.

2. The apparatus according to claim 1, wherein
the scanning mechanism includes a stage configured to hold the substrate, and a driving mechanism configured to move the stage along a moving path parallel to the first direction, and
at least a part of the second region is arranged above the moving path.

3. The apparatus according to claim 1, wherein
in a planar view, the first region and the second region are apart in the first direction.

4. The apparatus according to claim 1, wherein
a size of the plurality of heads in a second direction orthogonal to the first direction is larger than a size of the substrate in the second direction in a state in which the substrate is held by the scanning mechanism.

5. The apparatus according to claim 1, wherein
in the second region, maintenance is performed for the head arranged in the second region in the plurality of heads.

6. The apparatus according to claim 5, further comprising a cleaning portion configured to clean the head arranged in the second region in the plurality of heads.

7. The apparatus according to claim 5, further comprising an inspection portion configured to inspect the head arranged in the second region in the plurality of heads.

8. The apparatus according to claim 7, wherein the inspection portion includes a measurement portion configured to measure a characteristic of the head arranged in the second region in the plurality of heads.

9. The apparatus according to claim 8, further comprising a processor configured to generate, based on a result of measurement by the measurement portion, correction data for controlling an operation of applying the droplets to the substrate in the coating region by the head measured by the measurement portion.

10. The apparatus according to claim 8, further comprising:
a second measurement portion configured to measure the head held by the moving mechanism in the plurality of heads; and
a processor configured to generate, based on a result of measurement by the measurement portion and the second measurement portion, correction data for controlling an operation of applying the droplets to the substrate in the coating region by the head.

11. The apparatus according to claim 10, wherein
the second measurement portion measures at least one of a position and a posture of the head held by the moving mechanism.

12. The apparatus according to claim 5, wherein
in the second region, the head arranged in the second region in the plurality of heads can be exchanged.

13. The apparatus according to claim 5, wherein
the plurality of heads include a first head and a second head, and
in the second region, a first maintenance portion configured to perform maintenance of the first head and a second maintenance portion configured to perform maintenance of the second head are arranged.

14. The apparatus according to claim 1, further comprising:
a maintenance portion configured to perform maintenance of the head arranged in the second region in the plurality of heads; and
a second conveying mechanism configured to move the maintenance portion in the first direction.

15. The apparatus according to claim 14, wherein
the second region includes a first section and a second section,
the first region is arranged between the first section and the second section, and
the second conveying mechanism is configured to be able to arrange the maintenance portion in any of the first section and the second section.

16. The apparatus according to claim 1, wherein
the moving mechanism is an elevating mechanism.

17. The apparatus according to claim 16, wherein
the first region is located at a position above the coating region.

18. The apparatus according to claim 1, wherein
the plurality of heads include a first head and a second head, and
the coating region includes a first position at which the first head is arranged such that the droplets are applied to the substrate by the first head, and a second position at which the second head is arranged such that the droplets are applied to the substrate by the second head, and the first position and the second position are different.

19. An article manufacturing method comprising:
applying droplets to a substrate by a coating apparatus; and
processing the substrate that has undergone the applying, thereby obtaining an article,
wherein the coating apparatus comprises:
a plurality of heads configured to discharge the droplets;
a conveying mechanism configured to convey the plurality of heads in a first direction such that one head in the plurality of heads is arranged in a first region and another head in the plurality of heads is arranged in a second region;
a moving mechanism configured to move one head in the plurality of heads between the first region and a coating region; and
a scanning mechanism configured to scan the substrate in the first direction such that the droplets are applied to the substrate by the head arranged in the coating region in the plurality of heads,
wherein at least a part of the second region is arranged above the scanning mechanism.
